(19) United States
(12) Patent Application Publication
(10) Pub. No.: US 2015/0259489 A1
(43) Pub. Date: Sep. 17, 2015

(54) PREPREG, METAL-CLAD LAMINATE AND PRINTED CIRCUIT BOARD

(71) Applicant: PANASONIC INTELLECTUAL PROPERTY MANAGEMENT CO., LTD., Osaka (JP)

(72) Inventors: Hiroaki UMEHARA, Osaka (JP); Hiroharu INOUE, Osaka (JP)

(73) Assignee: PANASONIC INTELLECTUAL PROPERTY MANAGEMENT CO., LTD., Osaka (JP)

(21) Appl. No.: 14/640,507

(22) Filed: Mar. 6, 2015

(30) Foreign Application Priority Data
Mar. 12, 2014 (JP) 2014-048598

(51) Int. Cl. C08J 5/24; H05K 1/05

(52) U.S. Cl. CPC C08J 5/24; H05K 1/056; C08J 2371/12; C08J 2463/00; C08J 2471/12; C08J 2315/00; H05K 2201/029

(57) ABSTRACT

Provided is a prepreg that is formed by impregnating a fabric base material with a resin composition, then heating and drying. The resin composition includes (A) a polymer which has a specific structure, has no unsaturated bond between carbon atoms, has an epoxy number of from 0.2 to 0.8 eq/kg, and has a weight-average molecular weight of from 200,000 to 1,000,000; (B) a polyarylene-ether copolymer (PAE); and (C) an epoxy resin having two or more epoxy groups on a molecule. The component (B) is compatible with the component (A), and the component (C) is an epoxy resin that is incompatible with the component (A).

### CROSS-REFERENCE TO RELATED APPLICATIONS

This application claims the benefit of Japanese Application No. 2014-48598 filed on Mar. 12, 2014, which is incorporated herein by reference in its entirety.

### TECHNICAL FIELD

This invention relates to a prepreg, a metal-clad laminate formed using the prepreg, and a printed circuit board formed using the metal-clad laminate.

### BACKGROUND ART

As electronic devices become smaller and thinner, increasing use is being made of surface-mount packaged components as the electronic components provided in such electronic devices. Examples of such packages (PKG) include those in which a semiconductor chip is mounted on a substrate, such as chip-on-board (COB) packages. This type of package has a structure in which the semiconductor chip and the substrate are bonded together. Hence, owing to a difference between the coefficients of thermal expansion (CTE) of the semiconductor chip and the substrate, deformation such as warping of the package on account of temperature changes sometimes arises. In such packages, at a large warpage, the forces that separate the semiconductor chip from the substrate increase, lowering the connection reliability between the semiconductor chip and the substrate.

There also exists a desire for even smaller and thinner dimensions in electronic devices. To satisfy such a desire, efforts are being made to achieve smaller and thinner electronic components; such efforts have been accompanied by investigations aimed at lowering the thickness of the substrate within electronic component packages. The warpage mentioned above has a tendency to arise in such low thickness substrates, further increasing the desire to suppress warpage.

In order to make electronic devices multifunctional, the number of electronic components installed within a device must be increased. To satisfy this requirement, a form of packaging referred to as “package on package” (PoP) assembly is employed in which a plurality of subpackages are stacked on each other, mounted on a substrate, and further packaged. PoP packaging is commonly used in, for example, handheld devices such as smart phones and tablet computers. Because PoP is a form of packaging in which a plurality of subpackages are stacked together, the connection reliability and other characteristics of each subpackage become important. In the interest of increasing the connection reliability, the desire is to lower the warpage of each of the packages used as a subpackage.

Those materials currently proposed as substrate materials for reducing package warpage are materials that have been developed to achieve such characteristics as a high rigidity and a low CTE. Examples include the materials described in Japanese Unexamined Patent Publication Nos. 2006-137942, 2007-138152 and 2008-007756. In this art, as the rigidity becomes higher and the CTE becomes lower, warpage by the package decreases.

At the same time, the trends toward larger capacity and higher functionality in electronic devices have led to a demand for higher transmission speeds. Hence, printed circuit boards are required to have not only a good insulating reliability, but also better dielectric properties (low dielectric constant, low dielectric loss tangent). Yet, it has been found to be difficult to achieve a low dielectric constant using only a material having a high dielectric constant such as an epoxy resin. One known approach has been to combine specialized art such as a modified polyphenylene ether (PPE) and a hollow filler (see, for example, Japanese Unexamined Patent Publication Nos. 2004-269785 and H10-298407). Another approach has been art that blends a radical-polymerizable thermoset resin with an epoxy resin (see, for example, Japanese Unexamined Patent Publication No. 2008-133329).

However, although high-rigidity, low-CTE materials such as those described in Japanese Unexamined Patent Publication Nos. 2006-137942, 2007-138152 and 2008-007756 have been confirmed to have warp-reducing effects in specific package forms, because changing the package form results in a completely different warpage behavior, such materials lack versatility. Moreover, there is also a desire to increase the heat resistance of the package.

Materials such as the PPE and hollow filler described in Japanese Unexamined Patent Publication Nos. 2004-269785 and H10-298407 are materials which have considerable drawbacks in terms of handleability and cost. In addition, the PPE described in Japanese Unexamined Patent Publication No. 2004-269785 is known to generally have a high CTE and thus to be detrimental in terms of package warpage. Finally, in materials obtained by blending a radical-polymerizable thermoset resin with an epoxy resin as described in Japanese Unexamined Patent Publication No. 2008-133329, because the radical-polymerizable thermoset resin has a lower dielectric constant than the epoxy resin, such blending of resins has a dielectric constant-lowering effect, which poses a problem from the standpoint of flame retardance.

It is therefore an object of this invention to provide a prepreg, a metal-clad laminate and a printed circuit board which are capable of reducing package warpage and which are endowed with both an excellent heat resistance and excellent dielectric properties.

### SUMMARY OF INVENTION

Accordingly, in a first aspect, the invention provides a prepreg that is formed by impregnating a fabric base material with a resin composition, then heating and drying, which resin composition includes:

(A) a polymer which has a structure shown in structural formulas (I) and (II) below

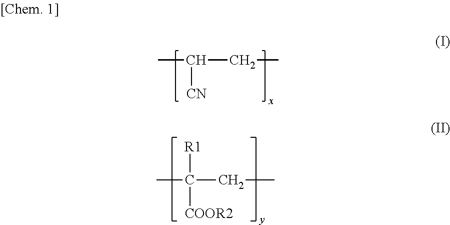

(wherein the ratio of x to y (x:y) is from 0:1 to 0.35:0.65, R1 is H or CH₃, and R2 is H or an alkyl group), has no unsaturated bond between carbon atoms, has an epoxy number of from 0.2 to 0.8 eq/kg, and has a weight-average molecular weight of from 200,000 to 1,000,000;

(B) a polyarylene-ether copolymer (PAE); and

(C) an epoxy resin having two or more epoxy groups on a molecule,

wherein the component (B) is compatible with the component (A), and the component (C) is an epoxy resin that is incompatible with the component (A).

### DESCRIPTION OF EMBODIMENTS

Embodiments of the invention are described below, although the invention is not limited to these embodiments.

The prepreg of this embodiment is formed by impregnating a fabric base material with a resin composition, then heating and drying until the resin composition assumes a semi-cured state (the so-called B-stage state).

The resin composition is an epoxy resin which includes the following components (A), (B) and (C).

In the present embodiment, when these three components of the resin composition are in a state where curing has not proceeded—that is, are merely resins which include no curing accelerator and the like, the component (B) is compatible with the component (A), and the component (C) is incompatible with the component (A), as a result of which phase separation occurs. Determinations as to whether these components are compatible or incompatible with each other can be carried out by the methods used in the subsequently described working examples of the invention. When the resin composition is in a semi-cured state or a cured state in which curing has proceeded (e.g., in a state where a curing accelerator is also included), the curing of components (B) and (C) proceeds and the component (A) is incompatible with the cured product of components (B) and (C), as a result of which the composition assumes a phase-separated state. Owing to the phase separation between the component (A) and the cured product of components (B) and (C), in the cured state of the prepreg, the rigidity can be increased by the cured product of components (B) and (C), and the elasticity can be lowered by the component (A).

Moreover, in laminates where the resin composition of this embodiment has been used, the elasticity is lowered, enabling the stress to be alleviated; hence, regardless of the form of the package, package warpage can universally be reduced. In addition, the dielectric properties of the laminate can be enhanced particularly with the component (B).

Accordingly, this invention makes it possible to provide prepregs, metal-clad laminates and printed circuit boards which are capable of reducing package warpage and which are endowed with both excellent heat resistance and excellent dielectric properties.

### Component (A): Polymer

The polymer serving as component (A) of this embodiment is a low-elasticity component, and specifically is an acrylic rubber having the structure shown in formulas (I) and (II) above. That is, the backbone of the component (A) is formed of the structure shown in formulas (I) and (II), with epoxy groups being bonded to the backbone. Because the ratio x:y is from 0:1 to 0.35:0.65, there are cases in which the backbone of the component (A) is composed solely of structures of formula (II). However, in all other cases, there is no particular limitation on the order in which the structures of formulas (I) and (II) are arranged.

Component (A) is a component which has no unsaturated bonds such as double bonds or triple bonds between the carbon atoms. That is, the carbon atoms of the component (A) are bonded therebetween by saturated bonds (single bonds). When unsaturated bonds are present between the carbon atoms, oxidation occurs over time, resulting to a loss of elasticity and embrittlement.

In addition, the component (A) has an epoxy number of from 0.2 to 0.8 eq/kg. At an epoxy number smaller than 0.2 eq/kg, there are fewer epoxy groups which react with the thermoset resin of the component (B) and the component (C). As a result, the thermoelastic properties of the component (A) become stronger, lowering the heat resistance of the package. Conversely, at an epoxy number larger than 0.8 eq/kg, the component (A) becomes compatible with components (B) and (C), as a result of which the glass transition temperature of the laminate (metal-clad laminate and printed circuit board) decreases and the heat resistance of the package worsens.

Component (A) is a polymer having a weight-average molecular weight (Mw) of from 200,000 to 1,000,000. At a weight-average molecular weight smaller than 200,000, the chemical resistance worsens. Conversely, at a weight-average molecular weight larger than 1,000,000, the moldability worsens.

By including this component (A) in the resin composition, moisture absorption by the cured product of this resin composition is minimized, as a result of which it is thought that the moisture resistance of the laminate can be increased and that the insulation reliability can be enhanced.

### Component (B): Polyarylene-Ether Copolymer (PAE)

The polyarylene-ether copolymer serving as component (B) of this embodiment is not particularly limited, provided it is compatible with the component (A).

Specifically, for example, the use of a polyarylene-ether copolymer having a number-average molecular weight (Mn) of from 500 to 2000 is preferred; the use of a polyarylene-ether copolymer with a Mn of 650 to 1500 is more preferred. At a molecular weight of 500 or more, it is possible to obtain a cured product having sufficient heat resistance. At a molecular weight of 2000 or less, the polyarylene-ether copolymer appears to be reliably compatible with the component (A) and, as curing proceeds, to easily react with the component (C). Moreover, the melt viscosity does not become too high, enabling sufficient fluidity to be obtained.

The number-average molecular weight of the polyarylene-ether copolymer serving as component (B) in this embodiment may be measured by, for example, gel permeation chromatography.

The component (B) is preferably a polyarylene-ether copolymer having an average of from 1.5 to 3 phenolic hydroxyl groups per molecule on molecular ends thereof. It is more preferable for there to be on average from 1.8 to 2.4 phenolic hydroxyl groups per molecule on molecular ends thereof. When the number of terminal hydroxyl groups is on average from 1.5 to 3, sufficient reactivity with the epoxy groups on the epoxy resin serving as the subsequently described component (C) can be achieved, further improving the heat resistance of the cured product, in addition to which the storage stability of the resin composition is good and the dielectric constant and loss tangent can be kept low.

The number of hydroxyl groups on the component (B) in this embodiment will be apparent from the specifications for the polyarylene-ether product that is used. The number of terminal hydroxyl groups may be, for example, a numerical value expressing the average number of hydroxyl groups per molecule for all the polyarylene-ether copolymer present in one mole of the component (B).

In addition, the component (B) has an intrinsic viscosity, as measured in 25° C. methylene chloride, of preferably from 0.03 to 0.12 dL/g, and more preferably from 0.06 to 0.095 dL/g. Within this intrinsic viscosity range, because the heat resistance of the cured product is enhanced and a sufficient fluidity can be obtained, it is presumed that molding defects can be better suppressed.

The intrinsic viscosity mentioned here also will be apparent from the specifications for the polyarylene-ether product that is used. Moreover, the intrinsic viscosity used here is the intrinsic viscosity measured in 25° C. methylene chloride, and more specifically is, for example, the value obtained by measuring, for example, a 0.18 g/45 mL methylene chloride solution (liquid temperature, 25° C.) with a viscometer. The viscometer is exemplified by the AVS 500 Visco System, available from Schott Instruments.

Illustrative examples of the polyarylene-ether copolymer serving as component (B) include polyarylene-ether copolymers made of 2,6-dimethylphenol and at least either of a bifunctional phenol or a trifunctional phenol, and polyarylene-ether copolymers composed primarily of a polyphenylene ether such as poly(2,6-dimethyl-1,4-phenylene oxide). The bifunctional phenol is exemplified by tetramethylbisphenol A.

The polyarylene ether copolymer serving as component (B) is exemplified by polyarylene-ether copolymers having the structure shown in general formula (1) below.

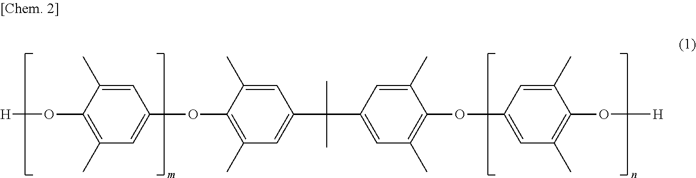

In formula (1), the letters m and n represent degrees of polymerization such that the copolymer falls within the above-indicated melt viscosity range. Specifically, the total value of m and n is preferably from 1 to 30, with m being preferably from 0 to 20 and n being preferably from 0 to 20. By using a polyarylene-ether copolymer constituted in this way, a resin composition which is endowed with better dielectric properties and which provides a cured product having a better heat resistance can be reliably obtained.

This polyarylene-ether copolymer can be prepared by, for example, the method described in International Publication No. WO 2007/067669. Alternatively, it is also possible to use as this polyarylene-ether copolymer a commercial product such as SA-90, available from SABIC's Innovative Plastics.

### Component (C): Epoxy Resin

The epoxy resin used as component (C) in this embodiment is not particularly limited, provided it is an epoxy resin having two or more epoxy groups on the molecule.

The number of epoxy groups here will be apparent from the specifications for the epoxy resin product that is used. The number of epoxy groups in the epoxy resin is exemplified by, specifically, a numerical value expressing the average number of epoxy groups per molecule for all the epoxy resin present in one mole of the epoxy resin.

Illustrative examples include bisphenol A-type epoxy resins, bisphenol F-type epoxy resins, biphenyl-type epoxy resins, cresol-novolak-type epoxy resins, dicyclopentadiene-type epoxy resins, naphthalene ring-containing epoxy resins, alicyclic epoxy resins, bromium-containing epoxy resins, and hydrogenated forms of any of these epoxy resins. These may be used singly or two or more may be used in combination.

The use of at least one type of epoxy resin selected from the group consisting of naphthalene ring-containing epoxy resins, dicyclopentadiene-type epoxy resins, and cresol-novolak-type epoxy resins is preferred. By using such an epoxy resin, a high Tg and a high heat resistance can be more reliably obtained. Moreover, phase separation with the component (A) readily arises, enabling the elasticity of the cured product to be lowered.

It is more preferable to use a naphthalene ring-containing epoxy resin; by doing so, it appears that the above properties can be more reliably achieved. A commercial product may be used as the naphthalene ring-containing epoxy resin. Illustrative examples include HP 9500, HP 4710 and HP 6000, all from DIC Corporation.

The mass ratio of components (A), (B) and (C) in the resin composition is not particularly limited, provided the resin composition has the properties described above. However, when the total amount of components (A), (B) and (C) is 100 parts by mass, it is preferable for the amount of the component (A) to be from 10 to 40 parts by mass. Including the component (A) within this range has the advantage of enabling the rigidity and low flexibility of the laminate to both be achieved without worsening the dielectric properties of the laminate.

The mixing ratios of the respective ingredients when preparing the resin composition of this embodiment can be suitably adjusted. For example, in the resin composition, it is desirable for the ratio of the total mass of components (B) and (C) to the mass of the component (A) to be from 90:10 to 60:40. From the standpoint of the dielectric properties, it is desirable for the mass ratio of the component (B), based on a total amount of (A), (B) and (C) of 100 parts by mass, to be from 40 to 85 parts by mass. From the standpoint of heat resistance, the mass ratio of components (B) and (C) is preferably such that the ratio of the epoxy equivalent mass of the component (C) to the hydroxyl equivalent mass of the component (B) (epoxy equivalent mass of the component (C)/hydroxyl equivalent mass of the component (B)) becomes from 1.0 to 4.0.

### Component (D): Inorganic Filler

In the above-described prepreg, this resin composition may further include (D) an inorganic filler.

The inorganic filler which may be used in this embodiment is not particularly limited. Illustrative examples of inorganic fillers include spherical silica, barium sulfate, silicon oxide powder, crushed silica, fired talc, barium titanate, titanium oxide, clay, alumina, mica, boehmite, zinc borate, zinc stannate, and other metal oxides and metal hydrates. When such inorganic fillers are included in the resin composition, the dimensional stability of the laminate can be increased.

In addition, using silica is advantageous because it also has the advantage of enabling the loss tangent (Df) of the laminate to be lowered.

When the resin composition includes the component (D), when the total amount of components (A), (B) and (C) is 100 parts by mass, it is preferable for the component (D) to be included in an amount within the range of from 0 to 300 parts by mass. If the amount of inorganic filler exceeds 300 parts by mass, warping of the PKG may increase owing to higher elasticity of the laminate and an increase in the CTE.

The resin composition of this embodiment may include also ingredients other than those described above, such as a curing accelerator. No particular limitation is imposed on the curing accelerator. For example, use may be made of imidazoles and their derivatives, organophosphorus compounds, metal soaps such as zinc octanoate, secondary amines, tertiary amines and quaternary ammonium salts. The resin composition may further include, for example, light stabilizers, viscosity modifiers and flame retardants.

### Prepreg

A resin composition can be prepared by blending together the above (A), (B) and (C), and optionally including also the component (D) and a curing accelerator. By then diluting this resin composition with a solvent, a varnish of the resin composition can be prepared.

Specifically, by way of illustration, first, of the resin composition described above, each ingredient which is capable of dissolving in an organic solvent is poured into the organic solvent and dissolved. At this time, heating may be carried out if necessary. Next, ingredients which are optionally used and do not dissolve in the organic solvent, such as inorganic fillers, are added and dispersion to a given dispersed state is effected using a ball mill, bead mill, planetary mixer or roll mill, thereby preparing the resin composition in the form of a varnish. The organic solvent used here is not subject to any particular limitation. Illustrative examples include ketone-type solvents such as acetone, methyl ethyl ketone and cyclohexanone, aromatic solvents such as toluene and xylene, and nitrogen-containing solvents such as dimethylformamide.

An example of a method for producing prepregs using the resin varnish thus obtained is one in which the resin varnish is impregnated into a fibrous base material, then dried. That is, the prepreg if this embodiment is one obtained by impregnating a fibrous base material with the resin varnish. With such a prepreg, it is possible to manufacture molded bodies such as printed circuit boards can fully suppress the occurrence of package warping and are also endowed with excellent heat resistance and dielectric properties.

Illustrative examples of the fabric base material used when producing prepregs include glass cloth, aramid cloth, polyester cloth, glass nonwoven fabric, aramid nonwoven fabric, polyester nonwoven fabric, wood pulp-based paper and cotton paper. By using glass cloth, a laminate having an excellent mechanical strength is obtained; glass cloth that has been subjected to flattening treatment is especially preferred. Flattening treatment may be carried out by, for example, continuously applying a suitable pressure to the glass cloth with a roller press so as to flatten and compress the yarn. The fabric base material used may be one having a thickness of, for example, from 10 to 200 μm.

Impregnation of the resin varnish into the fabric base material is carried out by dipping, coating or the like. If necessary, such impregnation may be repeated a plurality of times. When doing so, it is also possible to repeat impregnation using a plurality of resin varnishes having different compositions or concentrations and thereby adjust the composition and amount of resin in the manner ultimately desired.

The resin varnish-impregnated fabric base material is heated under the desired heating conditions, such as at 120 to 190° C. for 3 to 15 minutes, thereby giving a prepreg in a semi-cured state (B-stage).

### Metal-Clad Laminate and Printed Circuit Board

The metal-clad laminate according to this embodiment is obtained by placing metal foil on the prepreg, then molding under applied heat and pressure. Using such a metal-clad laminate, it is possible to manufacture printed circuit boards which fully suppress the occurrence of package warping and moreover are endowed with an excellent heat resistance and excellent dielectric properties.

In one illustrative example of a method for producing metal-clad laminates using the prepreg of this embodiment, a metal foil such as copper foil is placed on one side or on both the top and bottom sides of a single prepreg or a plurality of laminated prepregs, and the resulting assembly is integrally laminated by molding under applied heat and pressure, thereby giving a double sided metal-clad laminate or a single-sided metal-clad laminate.

Next, circuit formation is carried out by etching or otherwise partially removing the metal foil on the surface of the produced laminate, thereby giving a printed circuit board in which a conductor pattern has been provided as a circuit on the surface of the laminate. The printed circuit board of this embodiment, even when fabricated into the form of a package having semiconductor chips bonded thereto, is able to fully suppress the occurrence of warpage and moreover is endowed with an excellent heat resistance and excellent dielectric properties.

The major features of the art disclosed in this specification are summarized below.

The prepreg according to one aspect of the invention is formed by impregnating a fabric base material with a resin composition, then heating and drying. The resin composition includes:

(A) a polymer which has a structure shown in structural formulas (I) and (II) below

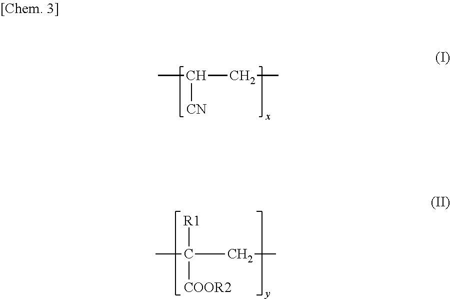

(wherein the ratio of x to y (x:y) is from 0:1 to 0.35:0.65, R1 is H or CH₃, and R2 is H or an alkyl group), has no unsaturated bond between carbon atoms, has an epoxy number of from 0.2 to 0.8 eq/kg, and has a weight-average molecular weight of from 200,000 to 1,000,000;

(B) a polyarylene-ether copolymer (PAE); and

(C) an epoxy resin having two or more epoxy groups on a molecule.

The component (B) is compatible with the component (A), and the component (C) is an epoxy resin that is incompatible with the component (A).

With such a structure, the elasticity of the laminate is lowered and stress can be alleviated, making it possible to provide a prepreg which can reduce warpage of the package and is endowed both with excellent heat resistance and excellent dielectric properties. In other words, the prepreg of the invention is a useful prepreg that achieves an excellent balance among the following: suppression of package warpage, heat resistance, and dielectric properties.

In the prepreg of the invention, the component (B) is preferably a polyarylene-ether copolymer having a number-average molecular weight of from 500 to 2000. This has the effect of making the component (B) compatible with the component (A). Moreover, in the semi-cured and cured states in which curing has proceeded, curing with the component (C) is accelerated, and the component (A) separates from the cured product of components (B) and (C), which presumably enables a prepreg cured product having a sufficient heat resistance to be obtained.

Furthermore, in the inventive prepreg, it is preferable for the component (B) to be a polyarylene-ether copolymer having an average of from 1.5 to 3 phenolic hydroxyl groups per molecule on molecular ends thereof. This has the effect of enabling sufficient reactivity to be obtained between the component (B) and the epoxy groups on the epoxy resin of the component (C), making the heat resistance of the cured product even better and also providing the resin composition with good storage stability, as well as making it possible to keep the dielectric constant and the dielectric loss tangent low.

Also, in the inventive prepreg, it is preferable for the component (B) to be made of 2,6-dimethylphenol and at least either of a bifunctional phenol or a trifunctional phenol. This is thought to enable the foregoing effects to be more reliably obtained.

Also, in the inventive prepreg, it is preferable for the component (C) to be at least one epoxy resin selected from the group consisting of naphthalene ring-containing epoxy resins, dicyclopentadiene-type epoxy resins and cresol novolak-type epoxy resins. This appears to have the effect of enabling a higher Tg and an even better heat resistance to be achieved. Moreover, phase separation with the component (A) occurs more easily, which is thought to enable the elasticity of the cured product to be lowered.

Furthermore, in the inventive prepreg, when the total amount of components (A), (B) and (C) is 100 parts by mass, the amount of the component (A) is preferably from 10 to 40 parts by mass. This has the effect of enabling both good dielectric properties and a good heat resistance to be achieved in a metal-clad laminate. Moreover, because the laminate exhibits a low elasticity, it is believed that package warpage can be reduced.

In the prepreg of the invention, the resin composition may further include (D) an inorganic filler. In this case, when the total amount of components (A), (B) and (C) is 100 parts by mass, the amount of the component (D) is preferably from 0 to 300 parts by mass. This is thought to have the effect of enabling an even lower loss tangent to be achieved.

The metal-clad laminate according to another aspect of the invention is obtained by placing metal foil on the prepreg of the foregoing aspect of the invention, then molding under applied heat and pressure. The printed circuit board according to yet another aspect of the invention is obtained by partially removing the metal foil on the surface of such a metal-clad laminate.

By virtue of such an arrangement, even when the prepreg of the invention is ultimately rendered into the form of a package in which semiconductor chips or the like have been bonded, the occurrence of warpage can be fully suppressed, enabling metal-clad laminates and, in turn, printed circuit boards having a high heat resistance and excellent dielectric properties to be provided.

The invention is illustrated more fully below by way of examples, although these examples in no way limit the scope of the invention.

### EXAMPLES

First, each of the ingredients used when preparing the resin composition in the examples is described.

Component (A): Polymer
Polymer 1: An acrylic rubber available from Nagase Chemtex Corporation as “SG-P3” (in the formula, R1 is hydrogen atoms, R2 is butyl groups and ethyl groups; the epoxy number is 0.2 eq/kg; Mw=850,000)
Polymer 2: An acrylic rubber available from Nagase Chemtex Corporation as “SG-P3LC Kai 24” (in the formula, R1 is hydrogen atoms and methyl groups, R2 is methyl groups, butyl groups and ethyl groups; the epoxy number is 0.2 eq/kg; Mw=650,000)
Polymer 3: An acrylic rubber available from Nagase Chemtex Corporation as “SG-P3-Mw1” (in the formula, R1 is hydrogen atoms, R2 is butyl groups and ethyl groups; the epoxy number is 0.2 eq/kg; Mw=260,000)
Polymer 4: An acrylic rubber available from Nagase Chemtex Corporation as “SG-P3 Kai 104” (in the formula, R1 is hydrogen atoms, R2 is butyl groups and ethyl groups; the epoxy number is 0.4 eq/kg; Mw=850,000)
Polymer 5: An acrylic rubber available from Nagase Chemtex Corporation as “SG-P3 Kai 179” (in the formula, R1 is hydrogen atoms, R2 is butyl group and ethyl groups; the epoxy number is 0.7 eq/kg; Mw=850,000)

### Component (B): PAE

PAE 1: SA 90, available from SABIC's Innovative Plastics (number-average molecular weight, 1500; number of hydroxyl groups, 1.9; terminal hydroxyl group concentration, 1,270 μmol/g)
PAE 2: A polyarylene-ether copolymer (polyphenylene ether synthesized by the method described in International Publication No. WO 2007/067669; number-average molecular weight, 800; number of hydroxyl groups, 1.8; terminal hydroxyl group concentration, 2,250 μmol/g)
PAE 3: SA 120, available from SABIC's Innovative Plastics (number-average molecular weight, 2500; number of hydroxyl groups, 1.2; terminal hydroxyl group concentration, 400 μmol/g)

### Component (C): Epoxy Resin

Naphthalene-type epoxy resin: HP 9500, available from DIC Corporation
Dicyclopentadiene-type epoxy resin: HP 7200H, available from DIC Corporation
Cresol-novolak-type epoxy resin: N680, available from DIC Corporation
Triphenylmethane-type epoxy resin: VG 3101, available from Printec Co.

### Component (D): Inorganic Filler

Spherical Silica 1: Spherical silica SC2500-GFL (from Admatechs) that was surface-treated with hexyltrimethoxysilane (KBM3063, from Shin-Etsu Chemical Co., Ltd.)

### Curing Accelerator

2E4MZ: 2-Ethyl-4-imidazole (from Shikoku Chemicals Corporation)
Zinc octanoate: Available as “Zn-OCTOATE” from DIC Corporation

### Example 1

### Prepreg

First, the polyarylene-ether copolymer (PAE) SA90 and toluene were mixed together and the mixture was heated to 80° C., thereby dissolving the polyarylene-ether copolymer in the toluene to give a 50 mass % toluene solution of polyarylene-ether copolymer. Next, the epoxy resin and the polymer were added in the proportions shown in Table 1 to this toluene solution of the polyarylene-ether copolymer, after which complete dissolution was effected by 30 minutes of stirring. In addition, a curing accelerator and an inorganic filler were added and dispersion was carried out with a ball mill, thereby giving a resin composition in the form of a varnish (resin varnish).

Using this varnish, for the sake of convenience, two types of prepregs were prepared and used in the subsequent evaluations.

WEA116E glass cloth (#2116 type, manufactured by Nitto Boseki Co., Ltd.) was used in Prepreg 1. The glass cloth was impregnated with the resin varnish in such a way as to have the thickness after curing become 100 μm. The impregnated glass cloth was then heated and dried at 130° C. for 6 minutes until it acquired a semi-cured state, thereby giving Prepreg 1.

WEA1037E glass cloth (#1037 type, manufactured by Nitto Boseki Co., Ltd.) was used in Prepreg 2. The glass cloth was impregnated with the above-described resin varnish in such a way as to have the thickness after curing become 30 μm. The impregnated glass cloth was then heated and dried at 130° C. for 4 minutes until it acquired a semi-cured state, thereby giving Prepreg 2.

### Metal-Clad Laminate:

Laminate for Evaluating Dielectric Properties

Eight sheets of Prepreg 1 were laminated together, and 12 μm copper foil (3EC-VLP, from Mitsui Mining & Smelting Co., Ltd.) was arranged on both sides of the laminate, thereby giving an assembly to be pressed, and the copper foil was bonded to both sides by 90 minutes of applied heat and pressure under a temperature of 220° C. and a pressure of 30 kg/cm², giving a copper-clad laminate having a thickness of 800 mm.

Laminate for Evaluating Package Warpage

Two sheets of Prepreg 2 were laminated together, and 12 μm copper foil (3EC-VLP, from Mitsui Mining & Smelting Co., Ltd.) was arranged on both sides of the laminate, thereby giving an assembly to be pressed, and the copper foil was bonded to both sides by 90 minutes of applied heat and pressure under a temperature of 220° C. and a pressure of 30 kg/cm², giving a copper-clad laminate having a thickness of 60 mm.

Laminate for Other Evaluations

Two sheets of Prepreg 1 were laminated together, and 12 μm copper foil (3EC-VLP, from Mitsui Mining & Smelting Co., Ltd.) was arranged on both sides of the laminate, thereby giving an assembly to be pressed, and the copper foil was bonded to both sides by 90 minutes of applied heat and pressure under a temperature of 220° C. and a pressure of 30 kg/cm², giving a copper-clad laminate having a thickness of 200 mm.

### Examples 2 to 11, and Comparative Examples 1 to 3

Aside from changing the formulations of the resin composition as shown in Table 1, prepregs and copper-clad laminates were obtained in the same way as in Example 1.

Using the respective prepregs and copper-clad laminates obtained in the manner described above as test specimens, various evaluations and tests were carried out by the methods described below.

### Evaluations

### Compatibility:

The compatibility was evaluated by using a 50:50 mixed solution of two components and visually examining the films formed by the solvent casting method. The compatibility was rated as “Good” when the film was clear, and as “Poor” when the film was opaque. Evaluations were carried out using the following films.

Compatibility of (A) and (B)

A 20% methyl ethyl ketone (MEK) solution of component (A) and a 20% toluene solution of the component (B) were prepared, following which a mixed solution containing each component in a 50:50 solids ratio was prepared. The mixed solution was cast onto a glass plate and then dried at 130° C. for 5 minutes by vaporizing off the solvents, thereby forming a film.

Compatibility of (A) and (C)

A 20% methyl ethyl ketone (MEK) solution of component (A) and a 20% MEK solution of component (C) were prepared, following which a mixed solution containing each component in a 50:50 solids ratio was prepared. The mixed solution was cast onto a glass plate and then dried at 130° C. for 5 minutes by vaporizing off the solvent, thereby forming a film.

### Glass Transition Temperature (Tg):

Using the above copper-clad laminates from which the copper foil had been removed as the test specimens, the maximum value of tan 8 (loss elastic modulus/storage elastic modulus) obtained by dynamic mechanical analysis (DMA) was treated as Tg. Measurement was carried out using a dynamic mechanical spectrometer (DMS 6100, from SSI Nanotechnology KK) in the tension module and at a temperature rise rate of 5° C./min.

### Coefficient of Thermal Expansion (CTE):

Using the above copper-clad laminates from which the copper foil had been removed as the test specimens, the coefficient of thermal expansion in the planar direction at temperatures below the glass transition temperature of the resin cured product was measured by the thermomechanical analysis (TMA) method described in JIS C 6481. A TMA system (TMA 6000, from SII Nanotechnology KK) was used for measurement.

### Heat Resistance:

In general accordance with JIS C 6481, copper-clad laminates cut to a predetermined size were left to stand for 1 hour in thermostatic chambers set to 270° C., 280° C. and 290° C., after which they were removed from the chambers. The laminates were then visually examined and rated as “Very good” when swelling did not occur in the test specimens treated at 290° C., “Good” when swelling did not occur at 280° C., “Fair” when swelling did not occur at 270° C., and “Poor” when swelling occurred at 270° C.

### Elasticity:

Using the above copper-clad laminates from which the copper foil had been removed as the test specimens, the elastic modulus (25° C.) was measured by dynamic mechanical analysis (DMA). Measurement was carried out using a dynamic mechanical spectrometer (DMS 6100, from SSI Nanotechnology KK) in the tension module and at a temperature rise rate of 5° C./min.

### Package (PKG) Warpage:

First a simplified flip-chip (FC) mounted package (dimensions, 16×16 mm) for measuring the amount of package warpage was fabricated by using a reinforcing material (HCV5313HS, from Panasonic Corporation) to bond and thereby mount flip chips onto the substrate. The flip chips used here were silicon chips with dimensions of 15.06 mm×15.06 mm×0.1 mm on which were mounted 4,356 solider balls (height, 80 μm). The substrates used were the above-described metal-clad laminates from which the metal foil had been removed.

Next, warpage of the FC-mounted PKG was measured using a TherMoiré PS200 warpage measurement system (Akrometrix, Inc.) based upon the shadow moire measurement theory. The PKG warpage was determined as the difference between the maximum and minimum warpage when the FC-mounted PKG was heated from 25° C. to 260° C., then cooled back down to 25° C.

### Dielectric Properties (Dielectric Constant and Dielectric Loss Tangent):

The dielectric constants and dielectric loss tangents of the test substrate at 10 GHz were measured by the cavity resonator perturbation method. Specifically, the dielectric constants and loss tangents of the test substrates at 10 GHz were measured using a network analyzer (N5230A, from Agilent Technologies).

Appearance after Etching of Copper Foil from Copper-Clad Laminate (CCL):

The laminate obtained by etching off and removing the copper foil from the above copper-clad laminate was visually examined, and rated according to whether voids and skipping were observed.

Good: No voids or skipping
Poor: Voids, skipping and resin bleed observable on surface of 300×300 mm laminate
The results are presented in Table 1. Numerical values for each of the ingredients in the table represent parts by mass.

TABLE 1

| | | MOLEC- | | MOLEC- | NUMBER OF | | | | | |
|---|---|---|---|---|---|---|---|---|---|---|
| | | ULAR | EPOXY | ULAR | TERMINAL | | | | | |
| | | WEIGHT | VALUE | WEIGHT | HYDROXYL | EXAM- | EXAM- | EXAM- | EXAM- | EXAM- |
| | | (Mw) | (cc/kg) | (Mn) | GROUPS | PLE 1 | PLE 2 | PLE 3 | PLE 4 | PLE 5 |
| A | POLYMER 1 | 850000 | 0.2 | | | 20 | | | | |
| | POLYMER 2 | 650000 | 0.2 | | | | 20 | | | |
| | POLYMER 3 | 260000 | 0.2 | | | | | 20 | | |
| | POLYMER 4 | 850000 | 0.4 | | | | | | 20 | |
| | POLYMER 4 | 850000 | 0.7 | | | | | | | 20 |
| B | PAE 1 SA90 | | | 1500 | 1.9 | 60 | 60 | 60 | 60 | 60 |
| | PAE 2 (SEE WO 2007/067669) | | | 800 | 1.8 | | | | | |
| | PAE 3 SA120 | | | 2500 | 1.2 | | | | | |
| C | NAPHTHALENE-TYPE | | | | | 20 | 20 | 20 | 20 | 20 |
| | EPOXY RESIN | | | | | | | | | |
| | DICYCLOPENTANE-TYPE | | | | | | | | | |
| | EPOXY RESIN | | | | | | | | | |
| | CRESOL-NOVOLAX-TYPE | | | | | | | | | |
| | EPOXY RESIN | | | | | | | | | |
| | TRIPHENYLMETHANE-TYPE | | | | | | | | | |
| | EPOXY RESIN | | | | | | | | | |
| ACCELERATOR | 2E4MZ | | | | | 0.2 | 0.2 | 0.2 | 0.2 | 0.2 |
| | ZINC OCTANOATE | | | | | 1 | 1 | 1 | 1 | 1 |
| D | SPHERICAL SILICA I | | | | | | | | | |
| | TOTAL | | | | | 101.2 | 101.2 | 101.2 | 101.2 | 101.2 |
| | COMPATIBILITY A/B | | | | | GOOD | GOOD | GOOD | GOOD | GOOD |
| | COMPATIBILITY A/C | | | | | POOR | POOR | POOR | POOR | POOR |
| | Tg(° C.) | | | | | 210 | 210 | 208 | 208 | 203 |
| | CTE (ppm/° C.) | | | | | 9 | 9 | 9.5 | 9.2 | 9.6 |
| | HEAT RESISTANCE | | | | | VERY | GOOD | FAIR | VERY | GOOD |
| | | | | | | GOOD | | | GOOD | |
| | ELASTIC MODULUS (Gpa) | | | | | 3 | 3.2 | 3.5 | 3.2 | 3.7 |
| | PKG WARPAGE (μm) | | | | | 438 | 450 | 460 | 455 | 490 |
| | DIELECTRIC CONSTANT | | | | | 3.7 | 3.7 | 3.7 | 3.7 | 3.8 |
| | (Dk AT 10 GHz) | | | | | | | | | |
| | LOSS TANGENT | | | | | 0.011 | 0.011 | 0.011 | 0.011 | 0.012 |
| | (Df AT 10 GHz) | | | | | | | | | |
| | APPEARANCE AFTER | | | | | GOOD | GOOD | GOOD | GOOD | GOOD |
| | ETCHING COPPER FOIL | | | | | | | | | |
| | FROM CCL | | | | | | | | | |

| | | | | | | | | | COM- | COM- | COM- |
|---|---|---|---|---|---|---|---|---|---|---|---|
| | | | | | | | | | PARATIVE | PARATIVE | PARATIVE |
| | | EXAM- | EXAM- | EXAM- | EXAM- | EXAM- | EXAM- | EXAM- | EXAM- | EXAM- | EXAM- |
| | | PLE 6 | PLE 7 | PLE 8 | PLE 9 | PLE 10 | PLE 11 | PLE 12 | PLE 1 | PLE 2 | PLE 3 |
| A | POLYMER 1 | 20 | 20 | 20 | 40 | 60 | 20 | 20 | 0 | 20 | 20 |
| | POLYMER 2 | | | | | | | | | | |
| | POLYMER 3 | | | | | | | | | | |
| | POLYMER 4 | | | | | | | | | | |
| | POLYMER 4 | | | | | | | | | | |
| B | PAE 1 SA90 | 60 | 60 | | 45 | 30 | 60 | 60 | 75 | 0 | 60 |
| | PAE 2 (SEE WO 2007/ | | | 60 | | | | | | | |
| | 067669) | | | | | | | | | | |
| | PAE 3 SA120 | | | | | | | | | 60 | |
| C | NAPHTHALENE-TYPE | | | 20 | 15 | 10 | 20 | 20 | 25 | 20 | |
| | EPOXY RESIN | | | | | | | | | | |
| | DICYCLOPENTANE- | 20 | | | | | | | | | |
| | TYPE EPOXY RESIN | | | | | | | | | | |
| | CRESOL-NOVOLAX- | | 20 | | | | | | | | |
| | TYPE EPOXY RESIN | | | | | | | | | | |
| | TRIPHENYLMETHANE- | | | | | | | | | | 20 |
| | TYPE EPOXY RESIN | | | | | | | | | | |
| ACCEL- | 2E4MZ | 0.2 | 0.2 | 0.2 | 0.15 | 0.1 | 0.2 | 0.2 | 0.25 | 0.2 | 0.2 |
| ERATOR | ZINC OCTANOATE | 1 | 1 | 1 | 0.75 | 0.5 | 1 | 1 | 1.25 | 1 | 1 |
| D | SPHERICAL SILICA I | | | | | | 100 | 200 | | | |
| | TOTAL | 101.2 | 101.2 | 101.2 | 100.9 | 100.6 | 201.2 | 301.2 | 101.5 | 101.2 | 101.2 |
| | COMPATIBILITY A/B | GOOD | GOOD | GOOD | GOOD | GOOD | GOOD | GOOD | — | POOR | GOOD |
| | COMPATIBILITY A/C | POOR | POOR | POOR | POOR | POOR | POOR | POOR | POOR | POOR | GOOD |
| | Tg(° C.) | 201 | 200 | 209 | 210 | 210 | 211 | 211 | 212 | 190 | 180 |
| | CTE (ppm/° C.) | 9.5 | 9.5 | 8.5 | 8 | 6 | 10 | 11 | 14 | 12 | 12 |
| | HEAT RESISTANCE | VERY | VERY | VERY | GOOD | FAIR | VERY | VERY | VERY | POOR | POOR |
| | | GOOD | GOOD | GOOD | | | GOOD | GOOD | GOOD | | |
| | ELASTIC MODULUS | 3.1 | 3.1 | 2.8 | 2 | 1.5 | 4 | 4.5 | 4 | 3.5 | 3.9 |
| | (Gpa) | | | | | | | | | | |
| | PKG WARPAGE (μm) | 455 | 454 | 430 | 400 | 380 | 510 | 530 | 600 | 500 | 530 |
| | DIELECTRIC | 3.7 | 3.7 | 3.8 | 3.8 | 3.9 | 4 | 4.1 | 3.6 | 3.7 | 3.7 |
| | CONSTANT (Dk AT | | | | | | | | | | |
| | 10 GHz) | | | | | | | | | | |
| | LOSS TANGENT | 0.011 | 0.011 | 0.012 | 0.014 | 0.016 | 0.0095 | 0.008 | 0.09 | 0.011 | 0.011 |
| | (Df AT 10 GHz) | | | | | | | | | | |
| | APPEARANCE AFTER | GOOD | GOOD | GOOD | GOOD | GOOD | GOOD | GOOD | GOOD | POOR | GOOD |
| | ETCHING COPPER FOIL | | | | | | | | | | |
| | FROM CCL | | | | | | | | | | |

As is apparent from the above results, by using the prepreg of the invention, a metal-clad laminate can be obtained which is able to fully suppress warpage and which moreover has an excellent heat resistance and excellent dielectric properties.

By comparison, in the prepreg of Comparative Example 1 which contains no component (A), the elastic modulus was large and the CTE was large, resulting in a large warpage. When the prepreg of Comparative Example 2 in which components (A) and (B) are incompatible was used, the appearance worsened and the heat resistance also became worse. When the prepreg of Comparative Example 3 in which the component (A) and the component (C) were compatible was used, phase separation after curing did not readily arise, the Tg decreased, and the elastic modulus of the laminate rose, as a result of which the PKG warpage worsened.

Moreover, among the results obtained in Examples 1 to 3, the sample from the working example 1 in which the polymer had a large molecular weight indicated that the dielectric properties were maintained and the laminate had a low elasticity and a low CTE, with no PKG warpage, demonstrating a high heat resistance. In Example 8, the dielectric properties were somewhat inferior, but the elasticity and CTE were lower and there was no PKG warpage, demonstrating a high heat resistance. In Examples 11 and 12 in which an inorganic filler was added as component (D), a high heat resistance and excellent dielectric properties were observed.

1. A prepreg formed by impregnating a fabric base material with a resin composition, then heating and drying, wherein the resin composition including:
(A) a polymer which has a structure shown in structural formulas (I) and (II) below 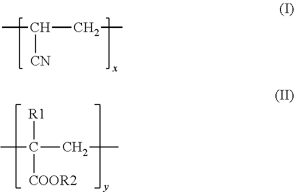
(wherein the ratio of x to y (x:y) is from 0:1 to 0.35:0.65, R1 is H or CH₃, and R2 is H or an alkyl group), has no unsaturated bond between carbon atoms, has an epoxy number of from 0.2 to 0.8 eq/kg, and has a weight-average molecular weight of from 200,000 to 1,000,000;
(B) a polyarylene-ether copolymer (PAE); and
(C) an epoxy resin having two or more epoxy groups on a molecule,
wherein the component (B) is compatible with the component (A), and
the component (C) is an epoxy resin that is incompatible with the component (A).

2. The prepreg according to claim 1, wherein the component (B) is a polyarylene-ether copolymer having a number-average molecular weight of from 500 to 2000.

3. The prepreg according to claim 1, wherein the component (B) is a polyarylene-ether copolymer having an average of from 1.5 to 3 phenolic hydroxyl groups per molecule on molecular ends thereof.

4. The prepreg according to claim 1, wherein the component (B) is made of 2,6-dimethylphenol and at least either of a bifunctional phenol or a trifunctional phenol.

5. The prepreg according to claim 1, wherein the component (C) is at least one epoxy resin selected from the group consisting of naphthalene ring-containing epoxy resins, dicyclopentadiene-type epoxy resins and cresol novolak-type epoxy resins.

6. The prepreg according to claim 1, wherein, when the total amount of the components (A), (B) and (C) is 100 parts by mass, the amount of the component (A) is from 10 to 40 parts by mass.

7. The prepreg according to claim 1, wherein the resin composition further includes (D) an inorganic filler.

8. The prepreg according to claim 7, wherein, when the total amount of the components (A), (B) and (C) is 100 parts by mass, the amount of the component (D) is from 0 to 300 parts by mass.

9. A metal-clad laminate obtained by laminating metal foil on the prepreg of claim 1, then molding under applied heat and pressure.

10. A printed circuit board obtained by partially removing metal foil on the surface of the metal-clad laminate of claim 9.
